(19) United States
(12) Patent Application Publication
(10) Pub. No.: US 2006/0101319 A1
(43) Pub. Date: May 11, 2006

(54) Input buffer device for de-rate matching in high speed turbo decoding block and method thereof

(75) Inventors: Dong-Wook Park, Suwon-si (KR); Joo-Kwang Kim, Yongin-si (KR); Weon-Heum Park, Chuncheon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/267,214

(22) Filed: Nov. 7, 2005

(30) Foreign Application Priority Data
Nov. 8, 2004 (KR) 90237/2004

(51) Int. Cl. H03M 13/00

(52) U.S. Cl. 714/755

(57) ABSTRACT

A high speed input buffer device for a turbo decoder and an input method thereof are provided. The input buffer device comprises a combing buffer for outputting stored symbols based on read addresses; a write MUX for dividing the output symbols into systematic, parity-1, and parity-2 symbols based on a BitSel signal, and outputting the divided symbols, first and second de-first rate matchers for individually performing a de-first rate matching operation with respect to the parity-1 and parity-2 symbols output from the write MUX, a data conversion unit generating code words, each of which contains a systematic symbol, a parity-1 symbol, and a parity-2 symbol, by using the systematic symbols output from the write MUX and the de-first-rate-matched parity-1 and parity-2 symbols, an input buffer unit having a double buffer structure, containing code blocks corresponding to the plurality of turbo decoders, storing each of the code words in a memory area of a code block corresponding to a decoder distinction signal which represents one of the turbo decodes, and outputting the stored code words to relevant turbo decoders, and a buffer controller for providing the input buffer unit with the decoder distinction signal, and providing the write MUX with the BitSel signal for dividing the output symbols into systematic, parity-1, and parity-2 symbols. Since the number and the area of memory elements required for the input control for a decoder are reduced, processing time, the error occurrence rate upon realizing the chip, and power consumption can be reduced.

### PRIORITY

This application claims the benefit under 35 U.S.C. 119(a) of Korean Patent Application Serial No. 2004-90237 filed in the Korean Intellectual Property Office on Nov. 8, 2004, the entire contents of which are hereby incorporated by reference.

### BACKGROUND OF THE INVENTION

1. Field of the Invention

The present invention relates to turbo decoding. More particularly, the present invention relates to a high speed input buffer for a turbo decoder and an input method thereof.

2. Description of the Related Art

Mobile communication systems are developing toward high-speed and high-quality radio data packet communication systems capable of providing data services and multimedia services beyond the initial voice-centered services. Currently, the standardizations for the High Speed Downlink Packet Access (HSDPA) and the 1× Evolution Data and Voice (1×EV-DV) are progressing in the 3^{rd} Generation Partnership Project (3GPP) and 3GPP 2. It can be said that such labors for standardization are representative proof of efforts to obtain solutions for a 3^{rd} generation (3G) mobile communication system capable of providing high quality radio data packet transmission service at a high speed of at least 2 Mbps. Moreover, the 4^{th} generation (4G) mobile communication systems are intended to provide higher speed and higher quality multimedia service than the 3G mobile communication systems.

High speed decoding is one of technologies for providing high quality multimedia service at a high speed. According to the HSDPA scheme of the 3GPP, two stage rate matching is performed for synchronization between an input packet and an actual physical channel frame. A first rate matching is performed based on the soft capacity of a terminal. When capacity of the terminal is sufficient, the first rate matching is not performed, so that performance of de-first rate matching is not required. However, if capacity of the terminal is insufficient, a transmitting section performs only puncturing work with respect to transmission data as the first rate matching without any repetition work for the transmission data, and a receiving section performs only a zero-insertion operation with respect to received data as the de-first rate matching. The transmitting section does not puncture systematic symbols but performs a puncturing task with respect to only parity-1 and parity-2 symbols, so that the receiving section allows the systematic symbols to pass without zero insertion.

FIG. 1 is a block diagram illustrating the structure of an input unit for a decoder which includes a typical de-first rate matcher.

An input unit 100 includes a hybrid automatic repeat request (HARQ) combining buffer 110, a HARQ buffer controller 140, a code block segmentation (CBS) buffer controller 150, a de-first rate matcher 120, and a CBS buffer 130. The input unit 100 is connected to a turbo decoding block 160.

The HARQ buffer controller 140 receives the read addresses of input symbols from the HARQ combining buffer 110, and controls the HARQ combining buffer 110. The HARQ combining buffer 110 outputs stored symbols to the de-first rate matcher 120, based on the read addresses. The de-first rate matcher 120 performs a de-first rate matching operation with respect to the output symbols, and then transmits the resultant output symbols to the CBS buffer 130.

The CBS buffer controller 150 receives a write address from the de-first rate matcher 120, and controls the CBS buffer 130. The CBS buffer 130 outputs the symbols de-first-rate-matched by the de-first rate matcher 120 to the turbo decoding block 160, based on the write address.

The CBS buffer 130 is an input buffer of the turbo decoding block 160. A turbo encoder can process a maximum of 5,114 encoding symbols. Therefore, when a coding rate of ⅓ or less is applied, the number of input symbols for a decoder may be three or more times greater than “5,114.” However, it is impossible to decode three or more times the number of encoding symbols at the same time, so received symbols are divided into a predetermined amount of data to be decoded, and are then stored in the CBS buffer 130. The CBS buffer 130 has the structure of a double buffer so that the CBS buffer 130 can receive new data while turbo decoding is performed with respect to stored data.

For instance, as shown in FIG. 2, the CBS buffer 130 contains two CBS buffer clusters 220 and 230. Each CBS buffer cluster 220 or 230 includes a plurality of code blocks 222 to 226, each of which contains three memory elements 222A to 222C, 224A to 224C, or 226A to 226C. The three memory elements 222A to 222C, 224A to 224C, or 226A to 226C store a systematic symbol, a parity-1 symbol, and a parity-2 symbol, respectively.

Hereinafter, the structure of an input buffer for a turbo decoder will be described in detail with reference to FIG. 2.

Herein, in the case of using a ‘Chip Rate×16’ clock of 61.44 MHz, since the data rate of a turbo decoder cannot exceed 3 Mbps, three turbo decoders 240A to 240C connected in parallel with each other are used to support a maximum data rate of 7.2 Mbps. Therefore, each CBS buffer cluster 220 or 230 includes code block #0 222, code block #1 224, and code block #2 226, corresponding to the three turbo decoders 240A, 240B, and 240C, respectively.

The CBS buffer 130 includes two CBS buffer clusters 220 and 230, which alternately store and output a series of received symbols. First, the operation of storing symbols into the CBS buffer cluster #1 220 in a write mode will be described. Each of CBS buffer clusters #1 220 and #2 230 contains three code blocks #0 to #2 222 to 226. Each of the code blocks #0 222 to #2 226 contains three memory elements 222A to 222C, 224A to 224C, or 226A to 226C to store a systematic symbol, a parity-1 symbol, and a parity-2 symbol, respectively. The three memory elements have a physically-divided structure in order to simultaneously output a systematic symbol, a parity-1 symbol, and a parity-2 symbol.

Based on a write address input from the de-first-rate matcher 219 to the CBS buffer controller 150 once per clock cycle, the CBS buffer controller 150 generates and outputs a control signal for storing data output from the de-first rate matcher 219 or a write MUX 214 in the CBS buffer 130 to the CBS buffer 130, and generates and transmits a “BitSel” signal for distinguishing systematic, parity-1, and parity-2 symbols from each other to a read MUX 212 and the write MUX 214. The CBS buffer controller 150 selects code blocks 222 to 226, based on decoder distinction signals “decsel 0 to 2” generated from the turbo decoders #0 240A to #2 240C.

When combined symbols “CombOut” are input from the HARQ combining buffer 110, the write MUX 214 divides the input symbols into systematic, parity-1, and parity-2 symbols based on BitSel signals output from the CBS buffer controller 150, and then outputs the divided symbols.

That is, when the BitSel signal has a value of “0”, the input symbols, which are systematic symbols, are stored in the systematic memories 222A, 224A, and 226A, each of which is selected in the code blocks 222 to 226 based on the decoder distinction signal of the CBS buffer controller 150, in a regular sequence, without passing through the de-first rate matcher 219. When the BitSel signal has a value ‘1’ or ‘2’, the write MUX 214 selects and transmits a parity-1 symbol or parity-2 symbol to the de-first rate matcher 219 by using a MUX 216. The de-first rate matcher 219 performs a de-first rate matching operation with respect to the parity-1 symbol or parity-2 symbol, and distributes the de-first rate matched symbols to the parity-1 memories 222B, 224B, and 226B or the parity-2 memories 222C, 224C, and 226C, each of which is selected in the code blocks 222 to 226 based on the decoder distinction signals of the CBS buffer controller 150.

The de-first rate matcher 219 generates a read address for parity-1 or parity-2 symbol to be read at the next stage, and transmits the generated read address to the read MUX 212. The de-first rate matcher 219 generates and transmits a write address for the parity-1 or parity-2 symbols to the CBS buffer controller 150. Also, a systematic address generator 218 generates and transmits a read address for the next systematic symbol to the read MUX 212. Since systematic symbols are not objects for zero insertion, the systematic address generator 218 may be configured simply as a counter.

The read MUX 212 selects the systematic read address, parity-1 read address or parity-2 read address based on the BitSel signals, and then outputs the selected read address to the HARQ combining buffer 110. The HARQ combining buffer 110 outputs input symbols to the write MUX 214 based on the selected read addresses.

When all symbols are stored in the CBS buffer cluster #1 220 in the above-mentioned manner, the CBS buffer cluster #1 220 is shifted into a read mode. Then, symbols, which have been stored in the systematic memories 222A, 224A, and 226A, the parity-1 memories 222B, 224B, and 226B, and the parity-2 memories 222C, 224C, and 226C of the code blocks 222 to 226, are transmitted to relevant turbo decoders, based on the decoder distinction signals (decsel 0, 1, and 2) for distinguishing the turbo decoders #0 240A, #1 240B, and #2 240C from each other. In detail, in the case in which the CBS buffer cluster #1 220 is in a read mode, when the “decsel 0” has a value of “0”, the CBS buffer controller 150 provides a read address to the code block #0 222 of the CBS buffer cluster 230, so as to provide a systematic symbol and parity-1 symbol to the turbo decoder #0 240A. Also, in this case, when the “decsel 0” has a value of “1”, the CBS buffer controller 150 provides a read address to the code block #0 222 of the CBS buffer cluster 230, so as to provide a systematic symbol and parity-2 symbol to the turbo decoder #1 240B. The operations performed with respect to the “decsel 1” and “decsel 2” carried out in a similar manner as in the case of the “decsel 0”.

Referring to FIG. 2, while the CBS buffer cluster #1 220 operates in a write mode to write data from the HARQ combining buffer 110, the CBS buffer cluster #2 230 operates in a read mode to provide data to turbo decoders. During the next transmission time interval (TTI), the modes of the CBS buffer clusters #1 220 and #2 230 are interchanged with each other, so that the CBS buffer cluster #2 230 writes data from the HARQ combining buffer 110, and the CBS buffer cluster #1 220 provides data to relevant turbo clusters 240A to 240C.

Hereinafter, the operation timing of the conventional input buffer will be described with reference to FIGS. 1 to 4.

FIG. 3 is a timing diagram illustrating the operation of a CBS buffer using two code blocks.

Referring to FIG. 3, a CBS buffer includes two code blocks #0 and #1. Each of the code blocks #0 and #1 includes systematic, parity-1, and parity-2 memory elements for storing systematic symbols, parity-1 symbols, and parity-2 symbols, respectively.

First, the storing operation is performed with respect to the code block #0 as described below.

During a period in which the CBS buffer controller 150 generates a BitSel signal having a value of “0”, that is, during a systematic processing period, systematic symbols output from the HARQ combining buffer 110 are stored in the systematic memory elements of the CBS buffer cluster. During a period in which the CBS buffer controller 150 generates a BitSel signal having a value of “1”, that is, during a parity-1 processing period, parity-1 symbols output from the HARQ combining buffer 110 are subjected to the de-first rate matching procedure, and then are stored in the parity-1 memory element 222B of the code block #0 222. During a period in which the CBS buffer controller 150 generates a BitSel signal having a value of “2”, that is, during a parity-2 processing period, parity-2 symbols output from the HARQ combining buffer 110 are subjected to the de-first rate matching procedure, and then are stored in the parity-2 memory element 222C of the code block #0 222.

After the de-first rate matching procedures have been performed, the number of systematic symbols, the number of the parity-1 symbols and the number of the parity-2 symbols, become equal to each other, so that the lengths of the systematic, the parity-1, and the parity-2 processing periods becomes equal to each other.

During each period of the systematic, parity-1, and parity-2 processing periods, after the systematic, parity-1, or parity-2 symbol is stored in the code block #0 222 as described above, the next systematic, parity-1, or parity-2 symbol is stored in its relevant memory element of the code block #1 224 in the same manner.

FIG. 4 is a timing diagram illustrating the operation of a CBS buffer using three code blocks according to an exemplary implementation of the an embodiment of the present invention.

Referring to FIG. 4, a CBS buffer includes three code blocks #0, #1 and #2. Each of the code blocks #0, #1 and #2 includes systematic, parity-1, and parity-2 memory elements for storing systematic symbols, parity-1 symbols, and parity-2 symbols, respectively. Similarly to the case shown in FIG. 3, during each period of the systematic, parity-1, and parity-2 processing periods, after the systematic, parity-1, or parity-2 symbol is stored in its relevant memory element of the code block #0 222, the next systematic, parity-1, or parity-2 symbol is stored in its relevant memory element of the code block #1 224 in the same manner. In addition, during each period of the systematic, parity-1, and parity-2 processing periods, after the storing operation of the code block #1 224 is finished, the next systematic, parity-1, or parity-2 symbol is stored in its relevant memory element of the code block #2 226.

As shown in FIGS. 3 and 4, according to the conventional input buffer, the de-first rate matching procedures for parity-1 and parity-2 symbols are sequentially performed after the systematic symbols have been processed. Therefore, the conventional input buffer requires two CBS buffer clusters, each of which includes three code blocks consisting of three memory elements for the systematic, parity-1, and parity-2 symbols, respectively. Consequently, the conventional input buffer requires total 18 memory elements, thereby enlarging a chip size, causing high power consumption, and increasing an error occurrence rate when realizing the chip.

### SUMMARY OF THE INVENTION

Accordingly, the present invention has been made to address the above-mentioned problems occurring in the prior art. Exemplary embodiments of the present invention provide an input buffer device and input method thereof for simultaneously storing systematic, parity-1, and parity-2 symbols in one memory element by changing a sequential type de-first rate matching block to have a parallel structure.

To accomplish this object, in accordance with one aspect of the present invention, there is provided an input buffer device for a high-speed turbo decoding apparatus containing a plurality of turbo decoders, the input buffer device comprising a combing buffer for outputting stored symbols based on read addresses, a write MUX for dividing the output symbols into systematic, parity-1, and parity-2 symbols based on a BitSel signal, and outputting the divided symbols, first and second de-first rate matchers for individually performing a de-first rate matching operation with respect to the parity-1 and parity-2 symbols output from the write MUX, a data conversion unit generating code words, each of which contains a systematic symbol, a parity-1 symbol, and a parity-2 symbol, by using the systematic symbols output from the write MUX and the de-first-rate-matched parity-1 and parity-2 symbols, an input buffer unit having a double buffer structure, containing code blocks corresponding to the plurality of turbo decoders, storing each of the code words in a memory area of a code block corresponding to a decoder distinction signal which represents one of the turbo decodes, and outputting the stored code words to relevant turbo decoders, and a buffer controller for providing the input buffer unit with the decoder distinction signal, and providing the write MUX with the BitSel signal for dividing the output symbols into systematic, parity-1, and parity-2 symbols.

In accordance with another aspect of the present invention, there is provided an input buffer device for a high-speed turbo decoding apparatus containing a plurality of turbo decoders, the input buffer device comprising a read MUX for outputting read addresses for systematic, parity-1, and parity-2 symbols based on a BitSel signal, a combing buffer for outputting stored symbols based on the read addresses; a write MUX for dividing the symbols output from the combining buffer into systematic, parity-1, and parity-2 symbols based on the BitSel signal, and outputting the divided symbols, a systematic address generator for generating read addresses for the systematic symbols and providing the generated read addresses to the read MUX, first and second de-first rate matchers for individually performing a de-first rate matching operation with respect to the parity-1 and parity-2 symbols output from the write MUX, and generating and providing read addresses for the parity-1 and parity-2 symbols to the read MUX, a data conversion unit generating code words, each of which contains a systematic symbol, a parity-1 symbol, and a parity-2 symbol, by using the systematic symbols output from the write MUX and the de-first-rate-matched parity-1 and parity-2 symbols, an input buffer unit having a double buffer structure, containing code blocks corresponding to the plurality of turbo decoders, storing each of the code words in a memory area of a relevant code block, and outputting the stored code words to relevant turbo decoders, and a buffer controller for providing the input buffer unit with a decoder distinction signal which represents one of the turbo decoders, and providing the write MUX with the BitSel signal.

In accordance with still another aspect of the present invention, there is provided a method for inputting symbols for a high-speed turbo decoding apparatus containing a plurality of turbo decoders, the method comprising outputting symbols stored in a combining buffer, based on read addresses, dividing the output symbols into systematic, parity-1, and parity-2 symbols based on a BitSel signal, and outputting the divided symbols, individually performing a de-first rate matching operation with respect to the parity-1 and parity-2 symbols, generating code words, each of which contains a systematic symbol, a parity-1 symbol, and a parity-2 symbol, by using the systematic symbols and the de-first-rate-matched parity-1 and parity-2 symbols, storing each of the code words in a memory area of a code block, which corresponds to a decoder distinction signal representing one of the turbo decoders, from among code blocks corresponding to the turbo decoders, and outputting the stored code words to relevant turbo decoders.

### BRIEF DESCRIPTION OF THE DRAWINGS

The features and advantages of the present invention will be more apparent from the following detailed description taken in conjunction with the accompanying drawings, in which like reference numerals will be understood to refer to like parts, components and structures, where:

FIG. 1 is a block diagram illustrating the structure of an input unit for a decoder which includes a typical de-first rate matcher;

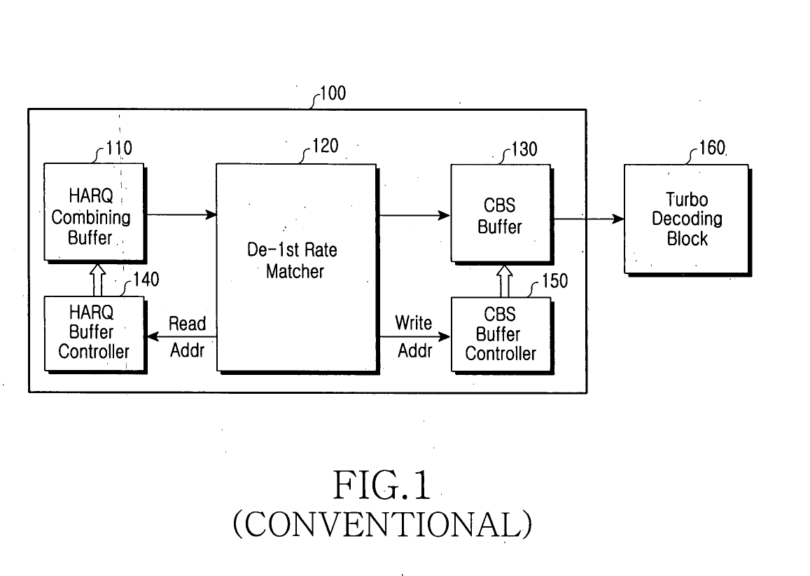

FIG. 2 is a block diagram illustrating the detailed structure of a typical input buffer device for a decoder;

FIG. 3 is a timing diagram illustrating the operation of a typical CBS buffer containing two code blocks;

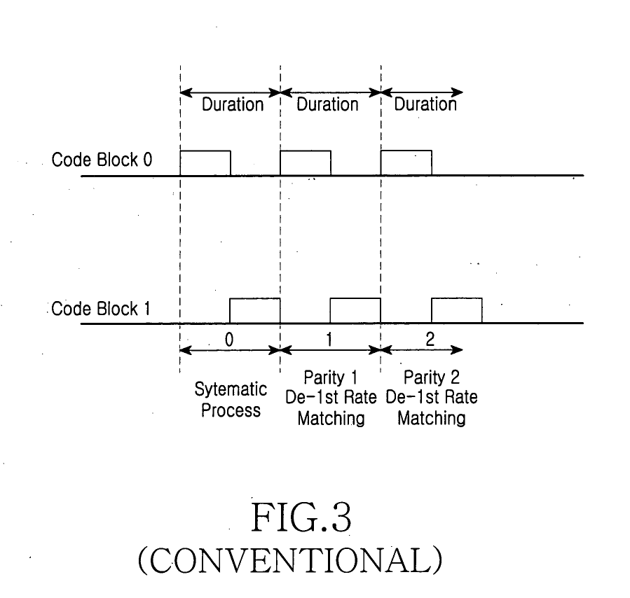

FIG. 4 is a timing diagram illustrating the operation of a typical CBS buffer containing three code blocks;

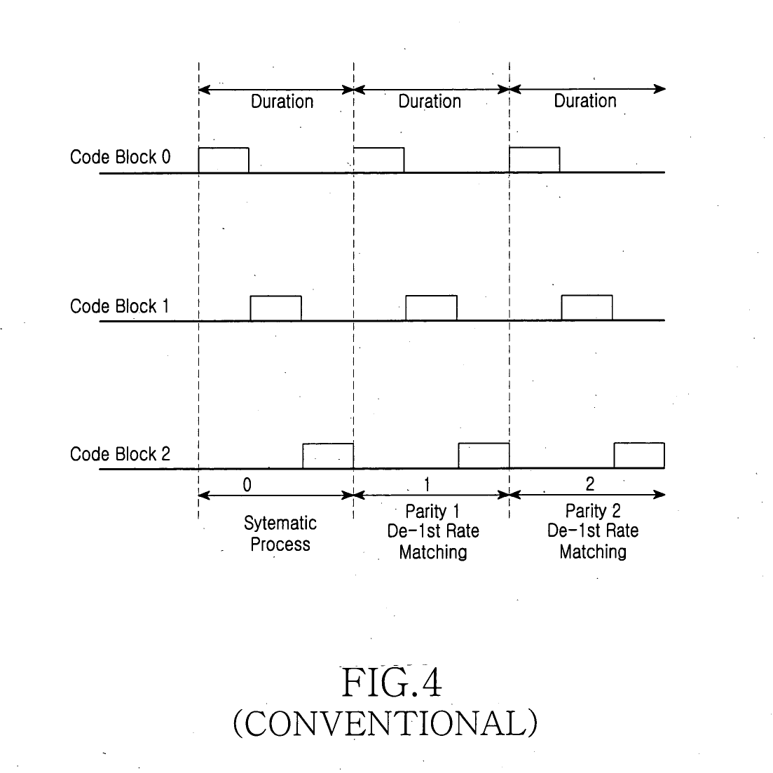

FIG. 5 is a block diagram illustrating a detailed structure of an input buffer device according to an exemplary embodiment of the present invention;

FIG. 6 is a timing diagram illustrating the operation of a CBS buffer containing two code blocks according to an exemplary embodiment of the present invention; and

FIG. 7 is a timing diagram illustrating the operation of a CBS buffer containing three code blocks according to an exemplary embodiment of the present invention.

### DETAILED DESCRIPTION OF EXEMPLARY EMBODIMENTS

Hereinafter, exemplary embodiments of the present invention will be described with reference to the accompanying drawings. It is to be noted that the same elements are indicated with the same reference numerals throughout the drawings. In the following description of the exemplary embodiments of the present invention, a detailed description of commonly known functions and configurations incorporated herein will be omitted for conciseness. In addition, the terminology used in the description is defined in consideration of the function of corresponding components used in the exemplary implementations of the embodiments of the present invention and may be varied according to users, operator's intention, or practices.

According to an embodiment of the he present invention there is a memory structure of an input buffer device for turbo decoding which can simultaneously perform read/write operations by storing systematic, parity-1, and parity-2 symbols in the same memory element, instead of storing each of them in a separate memory element.

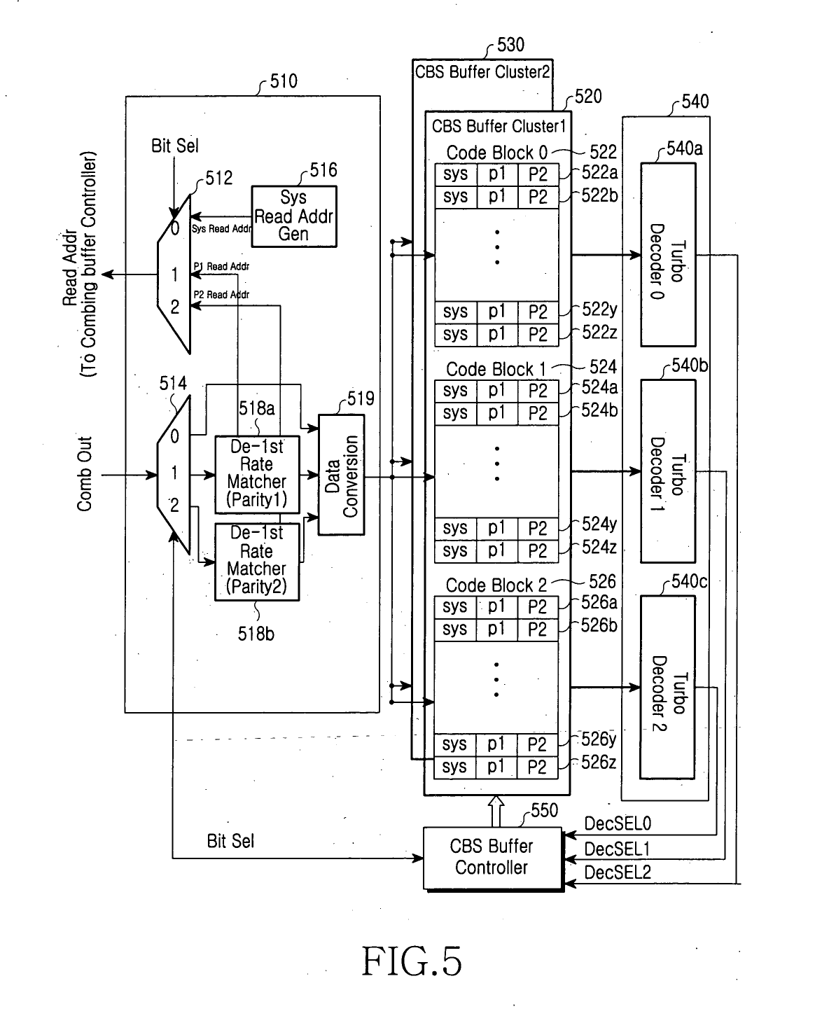

FIG. 5 is a block diagram illustrating a memory structure of an input buffer device according to an exemplary embodiment of the present invention.

The input buffer device includes two CBS buffer clusters #1 520 and #2 530, a CBS buffer controller 550 for controlling the CBS buffer clusters #1 520 and #2 530, and a de-first rate matcher 510.

A CBS buffer includes the two CBS buffer clusters #1 520 and #2 530, which respectively interchange their roles with each other between a write mode for storing received symbols and a read mode for outputting stored symbols to a turbo decoding block 540, every transmission time interval (TTI). Each of the CBS buffer clusters #1 520 and #2 530 contains three code blocks #0 522 to #2 526. Each of the code blocks #0 522 to #2 526 contains a plurality of memory areas 522A to 522Z, 524A to 524Z, or 526A to 526Z to store code words, each of which contains a systematic symbol, a parity-1 symbol, and a parity-2 symbol. In this drawing, the code block and memory areas of the CBS buffer cluster #2 530 are omitted. The code blocks #0 522 to #2 526 are configured with physically-divided memory elements. The memory areas 522A to 522Z, 524A to 524Z, or 526A to 526Z are logically distinguished based on read/write addresses.

The CBS buffer controller 550, once every three clock cycles, generates a write address for storing data output from a data conversion block 519 in the CBS buffer clusters #1 520 and #2 530, and generates a BitSel signal for distinguishing systematic, parity-1, and parity-2 symbols from each other and transmits the generated BitSel signal to a read MUX 512 and a write MUX 514. The CBS buffer controller 550 controls the operation of relevant code blocks 522 to 526 of the CBS buffer clusters #1 520 and #2 530, based on decoder distinction signals “Decsel 0 to 2” generated from the turbo decoders #0 540A to #2 540C.

When combined symbols “CombOut” are output from the HARQ combining buffer (not shown), the write MUX 514 divides the input symbols into systematic, parity-1, and parity-2 symbols based on the BitSel signals output from the CBS buffer controller 550, and then outputs the divided symbols. According to an exemplary implementation, when the BitSel signal has a value of “0”, the write MUX 514 transmits the input symbol, which is a systematic symbol, directly to the data conversion block 519 without performing de-first rate matching. When the BitSel signal has a value of “1”, the write MUX 514 transmits the input symbol, which is a parity-1 symbol, to the de-first rate matcher #1 518A. When the BitSel signal has a value of “2,” the write MUX 514 transmits the input symbol, which is a parity-2 symbol, to the de-first rate matcher #2 518B.

A systematic address generator 516 generates and transmits the read address for a systematic symbol desired for the next reading to the read MUX 512. The de-first rate matcher #1 518A generates and transmits the read address for a parity-1 symbol desired for the next reading to the read MUX 512. In addition, the de-first rate matcher #1 518A performs a de-first rate matching procedure with respect to parity-1 symbols transmitted from the write MUX 514, and then outputs the resultant symbols to the data conversion block 519. The de-first rate matcher #2 518B generates and transmits the read address for a parity-2 symbol desired for the next reading to the read MUX 512. In addition, the de-first rate matcher #2 518B performs a de-first rate matching procedure with respect to parity-2 symbols transmitted from the write MUX 514, and then outputs the resultant symbols to the data conversion block 519.

The read MUX 512 selects one address from among the systematic read address, parity-1 read address, and parity-2 read address based on a BitSel signal, and outputs the selected read address to the HARQ combining buffer. The HARQ combining buffer outputs input symbols based on the selected read addresses.

With respect to the systematic symbol and the parity-1 and parity-2 symbols having undergone the de-first rate matching procedure, the data conversion block 519, once every three clock cycles, generates a code word, which contains systematic, parity-1, and parity-2 symbols, to be matched with the bit width of the code blocks #1 522A to 522C, #2 524A to 524C #2 526A to 526C. The code words containing systematic, parity-1, and parity-2 symbols are distributed and stored in the divided memory areas 522A to 522Z, 524A to 524Z, or 526A to 526Z of relevant code blocks #0 522 to #2 526, based on a write address generated from the CBS buffer controller 550 every three clock cycles. According to an exemplary implementation, each of the memory areas 522A to 522Z, 524A to 524Z, and 526A to 526Z has a specific read/write address and can store one code word.

The code words stored in the memory areas 522A to 522Z, 524A to 524Z, and 526A to 526Z of the code blocks 522 to 526 are individually transmitted to relevant turbo decoders 540A to 540C based on the decoder distinction signals (decsel 0, 1, and 2), under the control of the CBS buffer controller 550. In detail, in the case in which the CBS buffer cluster #1 520 is in a read mode, when the “decsel 0” has a value of “1,” the CBS buffer controller 550 provides a read address for a specific code word to the code block #0 522 so that the code block #0 522 may provide the turbo decoder #0 540A with the specific code word containing systematic, parity-1, and parity-2 symbols. In this case, when the “decsel 1” has a value of “1,” the CBS buffer controller 550 provides a read address for a specific code word to the code block #1 524 so that the code block #1 524 may provide the turbo decoder #1 540B with the specific code word containing systematic, parity-1, and parity-2 symbols. Also, when the “decsel 2” has a value of “1,” the CBS buffer controller 550 performs a similar operation.

Meanwhile, when the CBS buffer cluster #2 530 is in a write mode, the CBS buffer cluster #2 530 stores code words output from the data conversion block 519 in memory areas of a relevant code block #0 to #2, based on write addresses provided from the CBS buffer controller 550. In the next TTI, the CBS buffer cluster #1 520 is shifted from a read mode to a write mode, while the CBS buffer cluster #2 530 is shifted from a write mode to a read mode. Then, each of the CBS buffer cluster #2 530 in the read mode and the CBS buffer cluster #1 520 in the write mode performs the operation as described above, based on its mode.

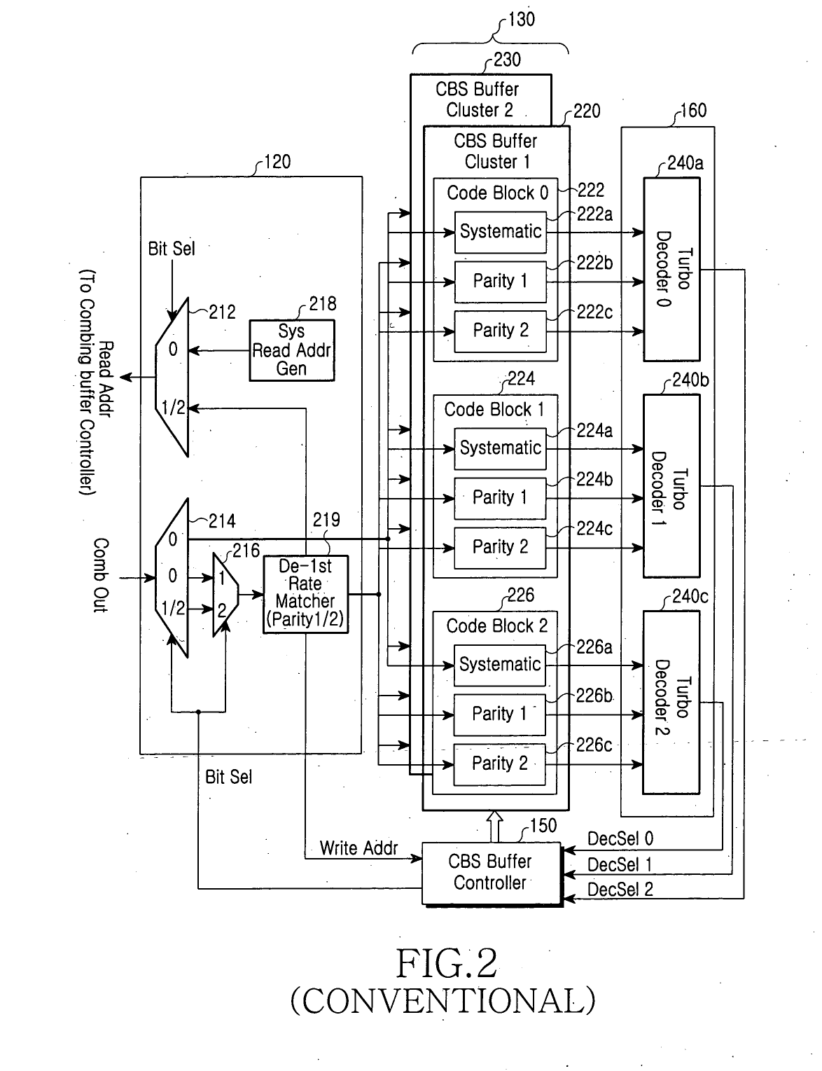

According to the conventional de-first rate matching described with reference to FIG. 2, after de-first rate matching for parity-1 symbols is finished, de-first rate matching for parity-2 symbols is performed. However, according to an exemplary implementation of an embodiment of the present invention as shown in FIG. 5, systematic, parity-1, and parity-2 symbols are processed one per one clock cycle by turns.

The de-first rate matchers #1 518A and #2 518B shown in FIG. 5 perform a de-first rate matching procedure using a zero-insertion algorithm with respect to each of parity-1 and parity-2 symbols. In this case, a read address of the HARQ combining buffer for each of parity-1 and parity-2 symbols desired for the next reading is independently generated.

Table 1 shows an exemplary form for input symbols which have been stored in the HARQ combining buffer.

TABLE 1

Systematic symbols
parity-1 symbols
parity-2 symbols

According to an exemplary implementation, as shown in Table 1, in the HARQ combining buffer, parity-1 symbols are stored following to systematic symbols, and parity-2 symbols are stored following to the parity-1 symbols. Therefore, an address generating scheme capable of reading the systematic, parity-1, and parity-2 symbols, which have been stored in each of the divided memory areas as described above, is required.

A scheme for generating a read address for the HARQ combining buffer according to an exemplary embodiment of the present invention is as follows.

<<Read address generation algorithm according to an exemplary embodiment of the present invention >>

if (BitSel == 0)
SysReadAddr = (SysReadAddr + 1)
else if (BitSel == 1)
P1ReadAddr = the number of stored systematic symbols + (P1_ID + 1)
else if (BitSel == 2)
P2ReadAddr = the number of stored systematic symbols + the number of
stored parity-1 symbols + (P2_ID + 1)

Herein, “SysReadAddr” represents a read address of a systematic symbol, “P1ReadAddr” represents a read address of a parity-1 symbol, and “P2ReadAddr” represents a read address of a parity-2 symbol. In addition, “P1_ID” represents the address of a previously-read parity-1 symbol, and “P2_ID” represents the address of a previously-read parity-2 symbol.

In detail, when a BitSel signal has a value of “0”, it indicates a systematic symbol, so the systematic address generator 516 generates a new systematic read address by adding “one” to the read address of a previous systematic symbol. When a BitSel signal has a value of “1”, it indicates a parity-1 symbol, so the de-first rate matcher #1 518A generates a new parity-1 read address “P1ReadAddr”, by adding the address “P1_ID” of a previous parity-1 symbol and “one” to the number of the total systematic symbols stored in the HARQ combining buffer. When a BitSel signal has a value of “2”, it indicates a parity-2 symbol, so the de-first rate matcher #2 518B generates a new parity-2 read address “P2ReadAddr”, by adding the address “P2_ID” of a previous parity-2 symbol and “one” to the sum of the number of total parity-1 symbols and the number of total systematic symbols stored in the HARQ combining buffer.

Hereinafter, the operation timing of an input buffer device according to an exemplary embodiment of the present invention will be described with reference to FIGS. 5 to 7. The number of code blocks used in an input buffer device is determined based on the amount of data received during one TTI, that is, based on the number of activated turbo decoders.

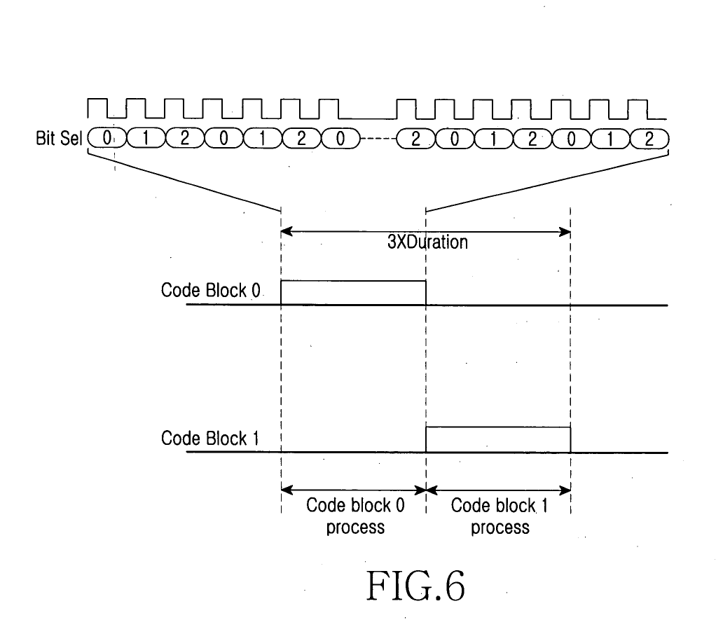

FIG. 6 is a timing diagram illustrating the operation of a CBS buffer cluster containing two code blocks #0 and #1 according to an exemplary embodiment of the present invention. The CBS buffer cluster is configured with two code blocks #0 and #1. Each of the code blocks #0 and #1 contains a plurality of memory areas, which have specific addresses in order to sequentially store code words containing systematic, parity-1, and parity-2 symbols. Although it is not shown, the operation timing of the code blocks is determined based on a decoder distinction signal.

First during a processing period for the code block #0, a storing operation as described below is performed.

A systematic symbol is read by the HARQ combining buffer when a BitSel signal input from the CBS buffer controller has a value of “0”, a parity-1 symbol is read when the BitSel signal has a value of “1”, and a parity-2 symbol is read when the BitSel signal has a value of “2”. The read systematic, parity-1, and parity-2 symbols are converted into a code word by a data conversion block, so as to have an input form suitable for the turbo decoder. The code word is stored in a first memory area. In such a manner, code words are all stored in the memory areas of the code block #0. In this case, code words may be stored in all or a part of memory areas depending on the amount of data received during on TTI.

Next, during a processing period for code block #1, code words are stored in all or a part of memory areas of the code block #1, similarly to the case of code block #0.

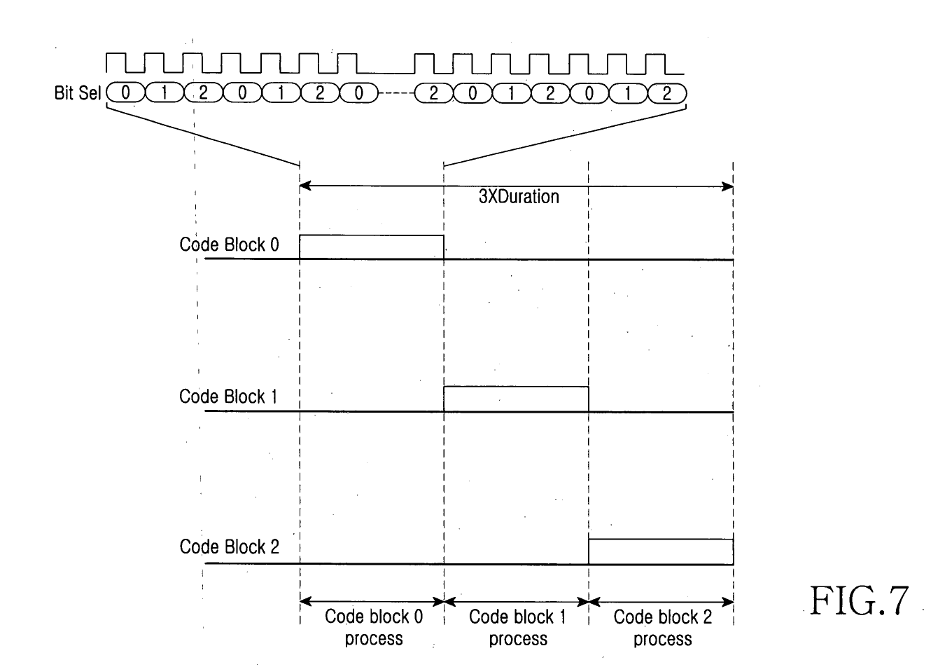

FIG. 7 is a timing diagram illustrating the operation of a CBS buffer cluster containing three code blocks according to an exemplary embodiment of the present invention. The CBS buffer cluster is configured with three code blocks #0, #1 and #2. Each of the code blocks #0, #1 and #2 contains a plurality of memory areas, which have specific addresses in order to sequentially store code words containing systematic, parity-1, and parity-2 symbols. Although it is not shown, the operation timing of the code blocks is determined based on a decoder distinction signal.

Similarly to the case of FIG. 6, during a processing period for the code block #0, a systematic symbol is read by the HARQ combining buffer when a BitSel signal input from the CBS buffer controller has a value of “0”, a parity-1 symbol is read when the BitSel signal has a value of “1”, and a parity-2 symbol is read when the BitSel signal has a value of “2”. The read systematic, parity-1, and parity-2 symbols are converted into a code word by a data conversion block so as to have an input form suitable for the turbo decoder. The code word is stored in a first memory area. After code words have been stored in all or a part of the memory areas of the code block #0, a processing period for code block #1 is begun. In the same manner, during the processing period for code block #1 and the processing period for code block #2, code words are stored in all or a part of memory areas of code block #1 or code block #2.

Through the above-mentioned storing operation, the systematic, parity-1, and parity-2 symbols contained in one code word can be simultaneously stored in one memory area having a specific address, and can be simultaneously read from the memory area.

Exemplary effects of the exemplary embodiments of the present invention will now be described.

The input buffer device performing a de-first rate matching procedure according to an exemplary embodiment of the present invention can reduce the number of required memory elements and can simplify the control logic of the buffer controller. In addition, since the number and the area of memory elements required for the input control for a decoder can be reduced, processing time, the error occurrence rate upon realizing the chip, and power consumption can be reduced.

While the present invention has been shown and described with reference to certain exemplary embodiments thereof, it will be understood by those skilled in the art that various changes in form and details may be made therein without departing from the scope of the invention as defined by the appended claims and the equivalents thereof.

What is claimed is:

1. An input buffer device for a high-speed turbo decoding apparatus comprising a plurality of turbo decoders, the input buffer device comprising:
a combing buffer for outputting stored symbols based on read addresses;
a write MUX for dividing the output symbols into systematic, parity-1, and parity-2 symbols based on a BitSel signal, and outputting the divided symbols;
first and second de-first rate matchers for individually performing a de-first rate matching operation with respect to the parity-1 and parity-2 symbols output from the write MUX;
a data conversion unit generating code words, each of the code words comprising a systematic symbol, a parity-1 symbol, and a parity-2 symbol, by using the systematic symbols output from the write MUX and the de-first-rate-matched parity-1 and parity-2 symbols;
an input buffer unit comprising a double buffer structure, the structure comprising code blocks corresponding to the plurality of turbo decoders, the input buffer unit storing each of the code words in a memory area of a code block corresponding to a decoder distinction signal which represents one of the turbo decodes, and outputting the stored code words to relevant turbo decoders; and
a buffer controller for providing the input buffer unit with the decoder distinction signal, and providing the write MUX with the BitSel signal for dividing the output symbols into systematic, parity-1, and parity-2 symbols.

2. The input buffer device as claimed in claim 1, wherein each of the code blocks comprises a physically-divided memory element, and a plurality of memory areas comprising specific addresses.

3. The input buffer device as claimed in claim 2, wherein the buffer controller receives the decoder distinction signal from the turbo decoding apparatus, and controls the output of the code words stored in memory areas of a code block corresponding to the decoder distinction signal to a relevant turbo decoder.

4. The input buffer device as claimed in claim 1, further comprising a read MUX for providing the combining buffer with at least one of the read addresses based on the BitSel signal.

5. The input buffer device as claimed in claim 4, further comprising a systematic address generator, which generates a new systematic symbol read address to read the systematic symbols from the combining buffer, and outputs the generated systematic symbol read address to the read MUX.

6. The input buffer device as claimed in claim 5, wherein the systematic address generator generates the new systematic symbol read address by adding a one to a previous systematic symbol read address.

7. The input buffer device as claimed in claim 4, wherein the first and second de-first rate matchers generate new parity-1 and parity-2 symbol read addresses for reading the parity-1 and parity-2 symbols from the combining buffer, and output the generated parity-1 and parity-2 symbol read addresses to the read MUX.

8. The input buffer device as claimed in claim 5, wherein the first de-first rate matcher generates a new parity-1 symbol read address by adding a previous parity-1 symbol address and a one to the number of the total systematic symbols stored in the combining buffer.

9. The input buffer device as claimed in claim 5, wherein the second de-first rate matcher generates a new parity-2 symbol read address by adding a previous parity-2 symbol address and a one to a sum of the number of total systematic symbols and the number of total parity-1 symbols, which have been stored in the combining buffer.

10. An input buffer device for a high-speed turbo decoding apparatus comprising a plurality of turbo decoders, the input buffer device comprising:
a read MUX for outputting read addresses for systematic, parity-1, and parity-2 symbols based on a BitSel signal;
a combing buffer for outputting stored symbols based on the read addresses;
a write MUX for dividing the symbols output from the combining buffer into systematic, parity-1, and parity-2 symbols based on the BitSel signal, and outputting the divided symbols;
a systematic address generator for generating read addresses for the systematic symbols and providing the generated read addresses to the read MUX;
first and second de-first rate matchers for individually performing a de-first rate matching operation with respect to the parity-1 and parity-2 symbols output from the write MUX, and generating and providing read addresses for the parity-1 and parity-2 symbols to the read MUX;
a data conversion unit for generating code words, each of the code words comprising a systematic symbol, a parity-1 symbol, and a parity-2 symbol, by using the systematic symbols output from the write MUX and the de-first-rate-matched parity-1 and parity-2 symbols;
an input buffer unit comprising a double buffer structure, the structure comprising code blocks corresponding to the plurality of turbo decoders, the input buffer unit storing each of the code words in a memory area of a relevant code block, and outputting the stored code words to relevant turbo decoders; and
a buffer controller for providing the input buffer unit with a decoder distinction signal which represents one of the turbo decoders, and providing the write MUX with the BitSel signal.

11. The input buffer device as claimed in claim 10, wherein each of the code blocks comprises a physically-divided memory element, and a plurality of memory areas comprising specific addresses.

12. The input buffer device as claimed in claim 11, wherein the buffer controller receives the decoder distinction signal from the turbo decoding apparatus, and controls the output of the code words stored in memory areas of a code block corresponding to the decoder distinction signal to a relevant turbo decoder.

13. The input buffer device as claimed in claim 10, wherein the systematic address generator generates the systematic symbol read address by adding a one to a previous systematic symbol read address.

14. The input buffer device as claimed in claim 10, wherein the first de-first rate matcher generates the parity-1 symbol read address by adding a previous parity-1 symbol address and a one to the number of the total systematic symbols stored in the combining buffer.

15. The input buffer device as claimed in claim 10, wherein the second de-first rate matcher generates the parity-2 symbol read address by adding a previous parity-2 symbol address and a one to a sum of the number of total systematic symbols and the number of total parity-1 symbols, which have been stored in the combining buffer.

16. A method for inputting symbols for a high-speed turbo decoding apparatus comprising a plurality of turbo decoders, the method comprising the steps of:
outputting symbols stored in a combining buffer, based on read addresses;
dividing the output symbols into systematic, parity-1, and parity-2 symbols based on a BitSel signal, and outputting the divided symbols;
individually performing a de-first rate matching operation with respect to the parity-1 and parity-2 symbols;
generating code words, each of the code words comprising a systematic symbol, a parity-1 symbol, and a parity-2 symbol, by using the systematic symbols and the de-first-rate-matched parity-1 and parity-2 symbols;
storing each of the code words in a memory area of a code block, which corresponds to a decoder distinction signal representing one of the turbo decoders, from among code blocks corresponding to the turbo decoders; and
outputting the stored code words to relevant turbo decoders.

17. The method as claimed in claim 16, wherein each of the code blocks comprises a physically-divided memory element, and a plurality of memory areas comprising specific addresses.

18. The method as claimed in claim 16, further comprising generating the new systematic symbol read address by adding a one to a previous systematic symbol read address, and providing the generated systematic read address to the combining buffer based on the BitSel signal.

19. The method as claimed in claim 16, further comprising generating a new parity-1 symbol read address by adding a previous parity-1 symbol address and a one to the number of the total systematic symbols stored in the combining buffer, and providing the generated parity-1 symbol read address to the combining buffer based on the BitSel signal.

20. The method as claimed in claim 16, further comprising generating a new parity-2 symbol read address by adding a previous parity-2 symbol address and a one to a sum of the number of total systematic symbols and the number of total parity-1 symbols which have been stored in the combining buffer, and providing the generated parity-2 symbol read address to the combining buffer based on the BitSel signal.
